(19) United States
(12) Patent Application Publication
(10) Pub. No.: US 2011/0286159 A1
(43) Pub. Date: Nov. 24, 2011

(54) MOBILE COMMUNICATION DEVICE

(75) Inventors: XIAO-LIANG WEI, Shenzhen City (CN); WEI-HUI FAN, Shenzhen City (CN)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 12/883,280

(22) Filed: Sep. 16, 2010

(30) Foreign Application Priority Data
May 20, 2010 (CN) 201010178781.5

(51) Int. Cl. H05K 5/00

(52) U.S. Cl. 361/679.01

(57) ABSTRACT

A mobile communication device includes a main body, a cover, a slide enabling assembly. The cover is attached to the cover. The slide enabling assembly is mounted between the base and the cover, the slide enabling assembly includes a retaining board mounted to the main body, a sliding board mounted to the cover, a bracket assembly and a button. The sliding board is slidably mounted to the retaining board by the bracket assembly; when the button is pushed, the bracket assembly impels the sliding board to slide and tilt relative to the retaining board so that the cover slides and tilts relative to the main body.

### BACKGROUND

1. Technical Field

This disclosure relates to slide and tilt mechanisms, particularly to a slide and tilt mechanism used in a mobile communication device.

2. Description of Related Art

As electronic devices continue to become more sophisticated, these devices provide an increasing amount of functionality by including such applications as, for example, a mobile phone, digital camera, video camera, navigation system, gaming capabilities, and Internet browser applications. Many of these devices with increased functionality have different configurations corresponding to use with the different functions. Fold and slide mechanisms have been widely used in different kinds of mobile electronic devices to accommodate these different configurations.

However in the conventional product configurations, the sliding and tilting mechanisms can be complicated and provide size inefficiencies as they tend to take up a lot of space.

Therefore, there is a room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary slide and tilt mechanism for mobile communication device. Moreover, in the drawings like reference numerals designate corresponding parts throughout the several views. Wherever possible, the same reference numbers are used throughout the drawings to refer to the same or like elements of an embodiment.

FIG. 1 is an exploded view of a mobile communication device with a slide and tilt mechanism according to an exemplary embodiment.

FIG. 2 is similar to FIG. 1, but showing the mobile communication device in another aspect.

FIG. 3 is an assembled view of the slide and tilt mechanism showed in FIG. 2.

FIG. 4 is an assembled view of the mobile communication device showed in FIG. 1.

FIG. 5 is an exemplary perspective view of the mobile communication device in a tilted configuration.

### DETAILED DESCRIPTION

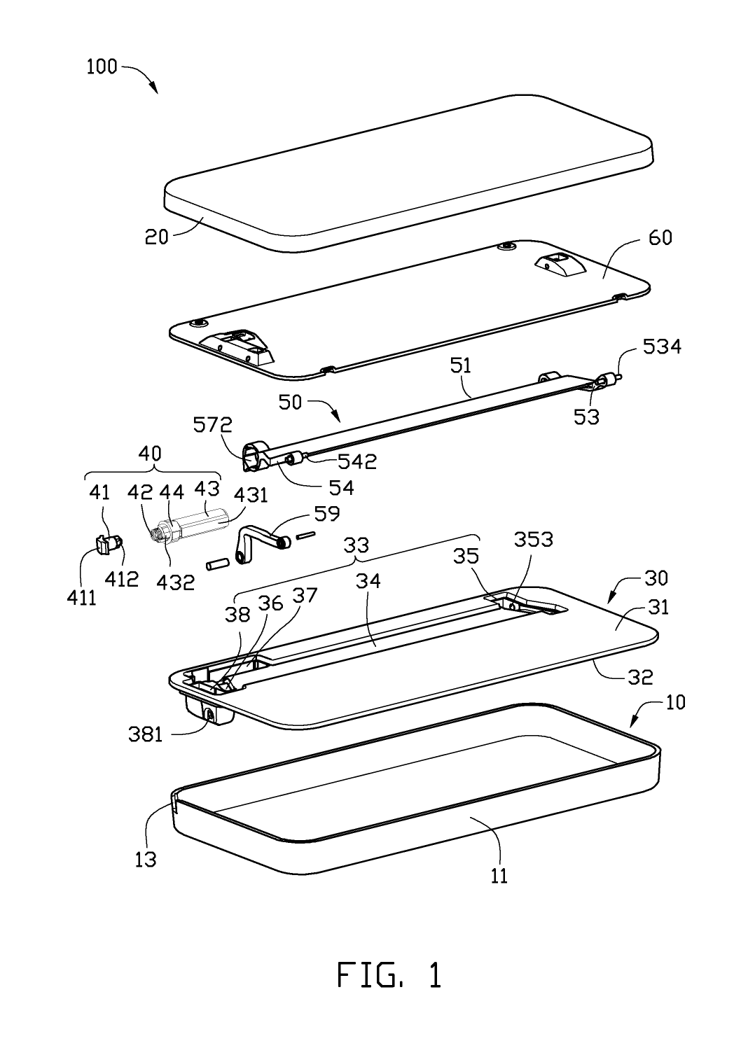

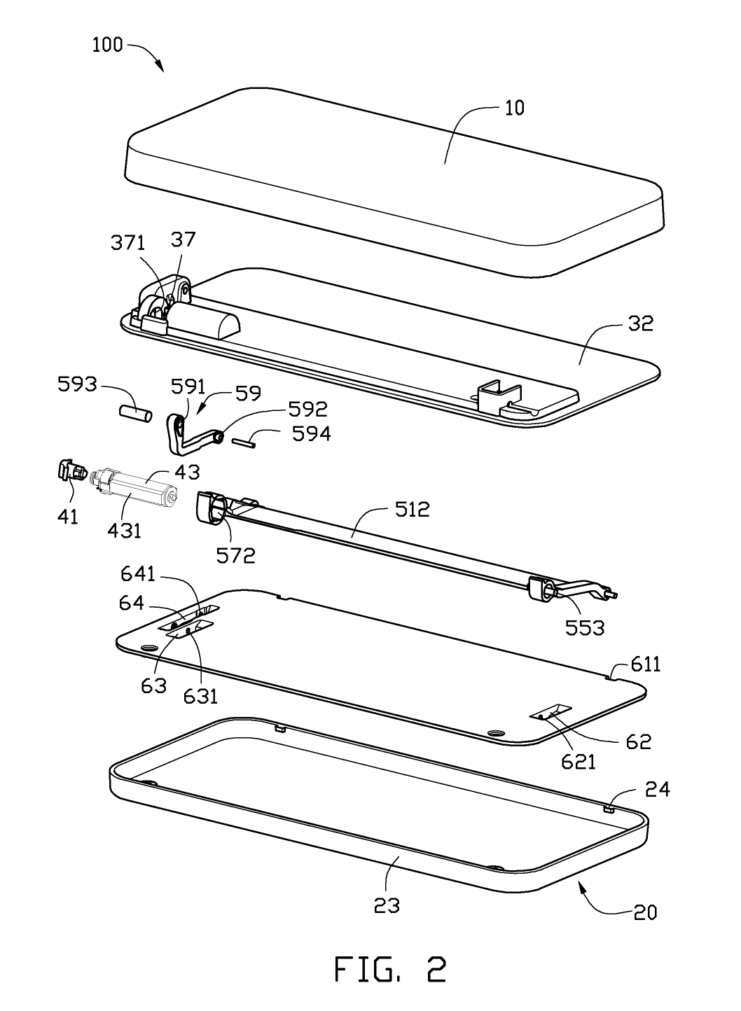

An embodiment of a mobile communication device 100 incorporating a slide and tilt mechanism is shown in FIGS. 1-2. The electronic device 100 includes a main body 10, a cover 20 and a slide enabling assembly (not labeled) coupled between the main body 10 and the cover 20. The slide enabling assembly includes a retaining board 30, an actuator 40, a bracket assembly (not labeled) and a sliding board 60. The cover 20 can tilt relative to the main body 10 when it slides relative to the main body 10 with the slide enabling assembly.

The main body 10 includes a peripheral wall 11 and a notch 13 defined in the peripheral wall 11. The cover 20 includes a sidewall 23 and two blocks 24 protruding from the sidewall 23. The retaining board 30 is mounted to the main body 10. The retaining board 30 includes a front surface 31, a back surface 32 opposite to the front surface 31 and a mounting portion 33 located at the front surface 31. The mounting portion 33 is for mounting the bracket assembly on the retaining board 30. In this exemplary embodiment, the mounting portion 33 includes a first receiving groove 34, a first latching groove 35, a second latching groove 36, a second receiving groove 37, and a third latching groove 38.

The first receiving groove 34 can be substantially rectangular and defined in the front surface 31. The first latching groove 35 is located at one end of the first receiving groove 34 and communicates with the one end of the first receiving groove 34. The retaining board 30 further defines two substantially aligned shaft holes 353, which are located in the first latching groove 35. The second latching groove 36 is located at the other end of the first receiving groove 34 and communicates with the first receiving groove 34. The second receiving groove 37 is recessed in the front surface 31 near the second latching groove 36 and communicates with the first receiving groove 34. The retaining board 30 further defines an opening 371 (FIG. 2) communicating with the second receiving groove 37. The third latching groove 38 is recessed in the front surface 31 near the second latching groove 36. The retaining board 30 further defines two substantially aligned first peg holes 381, which are located in the third latching groove 38.

The actuator 40 includes a button 41, an elastic element 42, a hinge 43 and a latching element 44. The button 41 includes a pressing portion 411 and a protrusion 412 protruding from the pressing portion 411. The hinge 43 includes a shell 431 and a cam 432, which is accommodated in the shell 431. The elastic element 42 is wrapped on the protrusion 412 and the cam 432. The latching element 44 is a ring non-rotatably wrapped about the cam 432. The shell 431 is mounted (e.g., tightly fitted) in the second receiving groove 37. The button 41 passes through the opening 371 into the second receiving groove 37 to actuate the hinge 43.

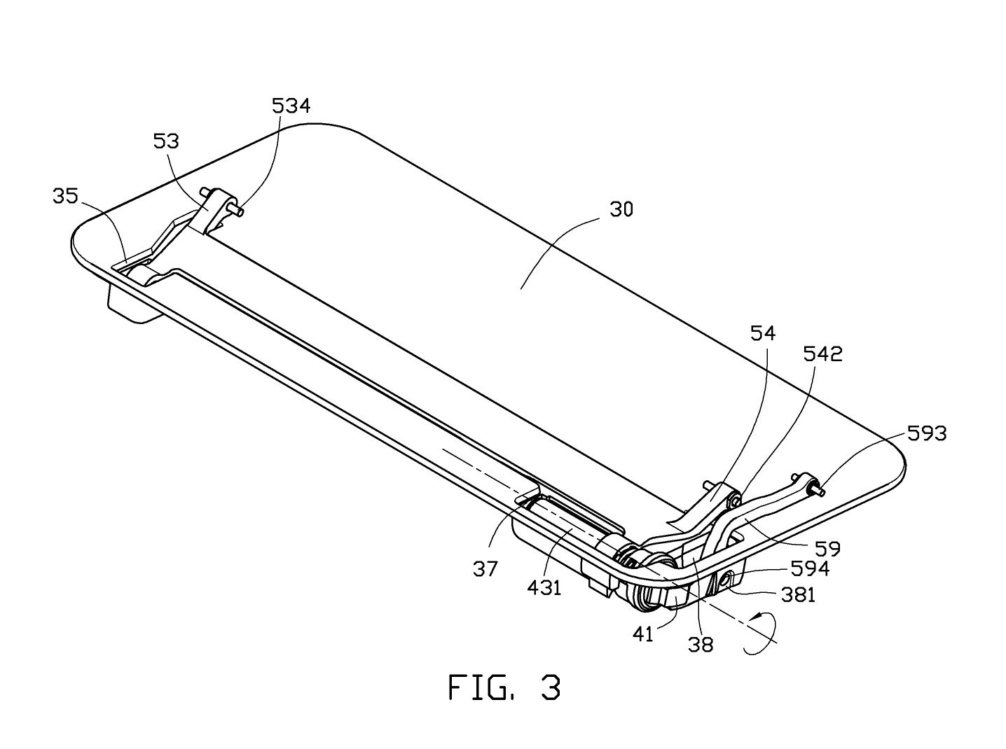

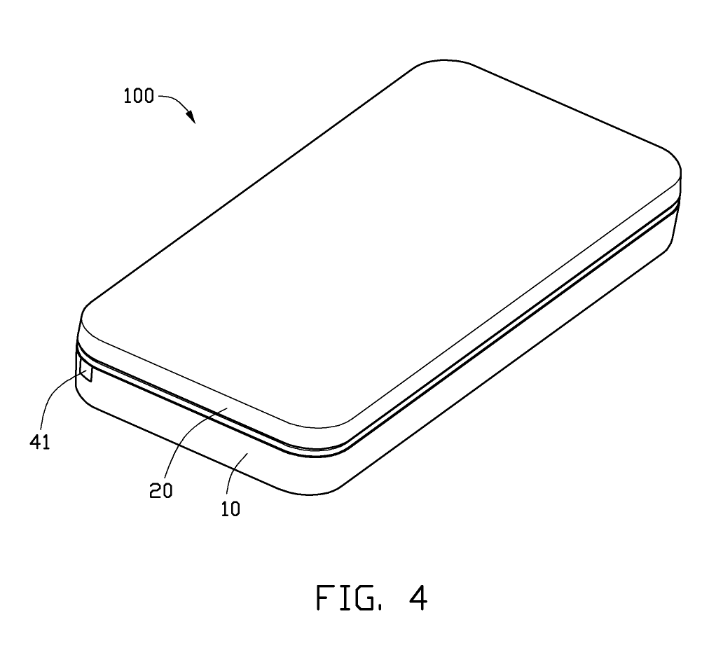

Referring to FIGS. 3 and 4, the bracket assembly includes a bracket 50 and a connecting rod 59. The bracket 50 includes a main board 51, a first connecting portion 53, which is located at one end of the main board 51 and a second connecting portion 54 located at another end of the main board 51. The first connecting portion 53 has a shaft 553 and a pin 534 respectively located near the opposite ends thereof. The opposite ends of the shaft 553 are respectively located at one of the shaft holes 353 so the first connecting portion 53 can rotate around the shaft 553 relative to the retaining board 30. The pin 534 is for rotatably affixing the first connecting portion 53 to the sliding board 60. The second connecting portion 54 has a latching hole 572 defined near one end thereof and a post 542 located near another end thereof. The latching hole 572 non-rotatably latches the latching element 44 therein so the second connecting portion 54 can rotate together with the cam 432 relative to the retaining board 30. The post 542 is for rotatably affixing the second connecting portion 54 to the sliding board 60.

The connecting rod 59 can be substantially L-shaped, defining a first eyelet 591 near one end thereof and a second eyelet 592 near the other end thereof. The bracket assembly further includes a first peg 593 located in the first eyelet 591 and a second peg 594 located in the second eyelet 592. The opposite end of the first peg 593 is respectively located at the first peg hole 381 so the connecting rod 59 can rotate around the first peg 593 relative to the retaining board 30. The second peg 594 is for rotatably affixing the connecting rod 59 to the sliding board 60.

The sliding board 60 is mounted to the cover 20. The sliding board 60 defines a first receiving slot 62 opposite to the first latching groove 35, a second receiving slot 63 opposite to the second latching groove 36, and a third receiving slot 64 opposite to the third receiving groove 38. The sliding board 60 further defines two pin holes 621 in the first receiving slot 62, two post holes 631 in the second receiving slot 63 and two second peg holes 641 in the third receiving slot 64. Each pin hole 621 rotatably accommodates one of opposite ends of the pin 534 to rotatably couple the first connecting portion 53 to the sliding board 60. Each post hole 631 rotatably accommodates one of opposite ends of the post 542 to rotatably couple the second connecting portion 54 to the sliding board 60. Each second peg hole 641 rotatably accommodates one of opposite ends of the second peg 594 to rotatably couple the connecting rod 59 to the sliding board 60. The sliding board 60 further defines two securing grooves 611 for latching with the blocks 24 to hold the sliding board 60 in the cover 20.

Referring to FIGS. 1 to 3, in assembly, the hinge 43 passes through the latching hole 572 until the latching element 44 is latched in the latching hole 572. The bracket 50 is mounted in the first receiving groove 34 with the opposite ends of the shaft 553 rotatably accommodated in the shaft holes 353 and the hinge 43 located in the second receiving groove 37. The elastic element 42 is wrapped about the cam 432 and then the button 41 passes through the notch 13 and the opening 371 until the protrusion 412 is inserted in the elastic element 42. The opposite ends of the first peg 593 are inserted in the first peg holes 591. The opposite ends of the second peg 594 are inserted in the second peg holes 641; the opposite ends of the pin are inserted in the pin holes 621; The opposite ends of the post are inserted in the post holes 631. The retaining board 30 is mounted (e.g., screwed) to the main body 10 and the sliding board 60 is mounted to the cover 20 by the latching engagement of the securing grooves 611 and the blocks 24.

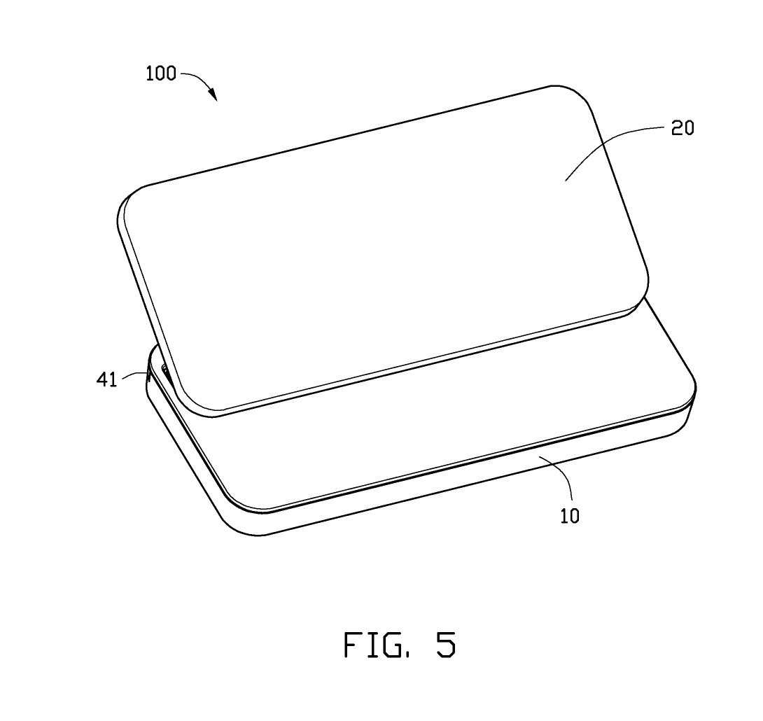

Referring to FIGS. 3-5, in use, the pressing portion 411 is pushed to compress the elastic element 42 causing the cam 432 to rotate relative to the shell 431, which makes the latching element 44 rotate relative to the shell 431. The latching element 44 latches with the latching hole 572 of the second connecting portion 54 so the second connecting portion 54 can rotate in the direction of the arrow shown in FIG. 3 after, the latching element 44 rotates relative to the shell 431. Once the second connecting portion 54 rotates, the first connecting portion 53 rotates about the shaft 553 and the pin 534. The connecting rod 59 rotates about the first peg 593 and the second peg 594 to tilt the sliding board 60 relative to the retaining board 30 so the cover 20 slides and tilts relative to the main body 10 like shown in FIG. 5.

It is to be understood, however, that even through numerous characteristics and advantages of the exemplary invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A mobile communication device, comprising:
a main body;
a cover attached to the main body; and
a slide enabling assembly mounted between the main body and the cover, the slide enabling assembly including a retaining board mounted to the main body, a sliding board mounted to the cover, a bracket assembly and a button;
wherein the sliding board is slidably mounted to the retaining board by the bracket assembly; when the button is pushed, the bracket assembly impels the sliding board to slide and tilt relative to the retaining board so that the cover slides and tilts relative to the main body.

2. The mobile communication device as claimed in claim 1, wherein the bracket assembly includes a bracket including a main board and a first connecting portion located at one end of the main board; one end of the first connecting portion is rotatably affixed to the retaining board by a shaft, another end of the first connecting portion is rotatably affixed to the sling board by a pin.

3. The mobile communication device as claimed in claim 2, wherein the retaining board defines two aligned shaft holes therein, the opposite ends of the shaft respectively locates at one of the shaft holes so the first connecting portion can rotate around the shaft relative to the retaining board.

4. The mobile communication device as claimed in claim 2, wherein the sliding board further defines two aligned pin holes therein, the opposite ends of the pin respectively locates at one of the pin holes so the first connecting portion can rotate around the pin relative to the sliding board.

5. The mobile communication device as claimed in claim 2, wherein the bracket further includes a second connecting portion located at another end of the main board, one end of the second connecting portion is rotatably affixed to the retaining board by a hinge, another end of the second connecting portion is rotatably affixed to the sling board by a post.

6. The mobile communication device as claimed in claim 5, wherein when the button is pushed, the hinge rotates to make the second connecting portion rotate relative to the retaining board.

7. The mobile communication device as claimed in claim 6, wherein once the second connecting portion rotates relative to the retaining board, the first connecting portion rotates about the shaft and the pin, to slide and tilt the sliding board relative to the retaining board so the cover slides and tilts relative to the main body.

8. The mobile communication device as claimed in claim 7, wherein the bracket assembly further includes a connecting rod, one end of the connecting rod is rotatably affixed to the retaining board by a first peg and another end of the connecting rod is rotatably affixed to the sliding board by a second peg.

9. The mobile communication device as claimed in claim 8, wherein the connecting rod rotates about the first peg and the second peg after the second connecting portion rotates relative to the retaining board.

10. The mobile communication device as claimed in claim 5, wherein the button includes a pressing portion and a protrusion protruding from the pressing portion; the hinge includes a shell mounted to the retaining board and a cam rotatably accommodating in the shell; the mobile communication device further includes an elastic element wrapping on the protrusion and the cam.

11. The mobile communication device as claimed in claim 10, further includes a latching element non-rotatably wrapping on the cam, the second connecting portion defines a latching hole which non-rotatably accommodates the latching element therein.
